(19) United States
(12) Patent Application Publication
(10) Pub. No.: US 2009/0042382 A1
(43) Pub. Date: Feb. 12, 2009

(54) Device packages

(76) Inventor: Barry Thomas Hawkey, Allentown, PA (US)

Correspondence Address: HITT GAINES, PC;LSI Corporation, PO BOX 832570, RICHARDSON, TX, 75083, US

(21) Appl. No.: 11/890,342

(22) Filed: Aug. 6, 2007

(51) Int. Cl. H01L 21/768

(52) U.S. Cl. 438/613; 257/E21.59

(57) ABSTRACT

Low volume production of electronic devices having ball attachments, e.g. solder ball arrays, is advantageously achieved using a specific method. In particular a stencil having holes in, for example, the ball grid array pattern is formed by laser ablation of the holes in materials such as paper and polymers. The stencil holes are aligned with corresponding pads on the electronic device. Balls such as solder balls are introduced into the holes and heated to induce adhesion of the balls to the corresponding pads.

### TECHNICAL FIELD

This invention related to the packaging of devices and in particular the packaging of devices such as integrated circuits.

### BACKGROUND OF THE INVENTION

Electronic devices such as integrated circuits and passive electronic devices are packaged in a variety of configurations. One widespread configuration involves the formation of a solder ball array on the exterior of the package to provide electrical communication between the package device and other components such as a printed circuit board or test socket. In such solder ball packaging a series of solder balls are adhered to conductive leads from the packaged device and spatially arranged in an array e.g. a grid of perpendicular rows and columns, with a solder ball at all or some of the column and row intersections.

The formation of such solder bump arrays for mass production i.e. production involving lots greater than 75 individual packages, where 5 to 40 individual packages are ganged together in a strip format, generally employs techniques such as the screen printing gravity method. (See the trade journal article titled “Solder Ball Attachment: an Equipment Overview” in the March 1998 issue of ChipScale Review Magazine, for a description of such mass production techniques.) However, mass production techniques are not efficient or cost effective for low volume applications. Typical low volume applications involve, for example, the repair or testing of mass produced components that have undergone solder ball attachment to a complementary device such as a circuit board. To test a device if it appears defective or to determine the cause of an apparent failure the package is removed from the complementary device typically by heating until the solder balls of the array melt. Clearly, this melting procedure severely deforms the solder balls and prevents the array from being employed in a test fixture or other configuration without repair of the array.

A common approach for reconstituting the solder ball array employs the use of a rigid metallic fixture such as an aluminum fixture. A typical fixture is shown in the plan view of FIG. 1 and has a metal body, 2, with recess, 5, whose perimeter, 4, is coextensive with the outer boundaries of the device to be repaired. The dots, 6, shown in recess, 5, correspond to holes positioned to overlay the points on the array of the device where solder bumps are to be placed. The holes are typically drilled using machine shop techniques generally involving small drill bits. In fact, the holes typically have a diameter in the range 0.014 to 0.016 inches, and thus drilling such holes generally results in frequent drill bit breakage. Additionally, since the holes are relatively closely spaced, e.g., center to center spacings in the range 0.5 to 0.8 mm, positioning the holes involve careful and time consuming machine shop procedures. Thus, fixtures such as shown of FIG. 1 are relatively expensive, often require relatively long, e.g. 1-½ to 2 month, periods of delay associated with machine shop preparation times, and require the provision of full blueprints to the machine shop. Such blueprints only add to the overall expense of repairing of the solder ball grid.

During the repair procedure the remnants of the original solder ball array are removed by melting and mechanical removal of excess solder from the device. A paste flux is then spread over the array region. This flux cleans the points of attachment for the solder balls and further facilitates the ball removal process by preventing smearing of the solder across the substrate. The fixture is then laid over the device so that the device is recessed into region 5 with its periphery at boundary 4. The orientation of the fixture is fixed so that the holes of the fixture align with the positions of solder ball attachment. A single solder ball is placed in each hole, 6, and the device heated to temperatures in the range 220 to 235 degrees Celsius. Accordingly, the balls adhere to the desired contact regions in the ball grid array but do not lose their generally spherical shape. The fixture is removed to leave the repaired array.

Because of the corrosive nature of the flux and because of the mechanical abrasion inherent in the procedure fixtures require periodic replacement. Such replacement further compounds the previously described costs and delays associated with the fixture preparation process. Therefore, a procedure that substantially reduces or eliminates such costs and delays would be quite desirable.

### SUMMARY OF THE INVENTION

The costs and delays associated with low volume fabrication of electronic devices with ball grids by a procedure involving a fixture is substantially reduced by employing for the fixture a material that is conducive to ablation by lasers having spot power densities in the range 1.2 to 5 watts/sq. mm. In particular, materials such as paper, e.g. paper card stock, and polymers e.g. polyvinyl materials such as Kapton™ (a registered trademark of E.I. DuPont de Nemours Corp.) with thicknesses typically in the range 0.005 to 0.012 inches are advantageously employed. The desired hole pattern having holes with diameters, for example, of 0.014 to 0.016 inches is produced by positioning the impact region of the laser beam using conventional computer control of the laser direction. Thus the point of ablation to form the desired hole is easily and precisely located by such conventional laser beam positioning techniques. For example, a graphical array hole pattern is made with a conventional AutoCAD program that is downloaded to a Markem 612 Platemaker. (This equipment is manufactured by Markem Corporation of Keene, N.H. and includes a sample holder and laser beam positioning component allowing beam position accuracy to ±0.00025 inches.)

The fixture, in the context of the invention denominated a stencil, is produced by laser ablation in, for example, flexible stock using a laser such as a carbon dioxide laser. Flexible stock is particularly useful in procedures involving devices having a dimension larger than 24 mm. Such devices often do not have a planar surface. A flexible stencil conforms to such non-coplanarity and allows more accurate alignment. In repair of a device a solder paste such as Alpha WS 600 (a paste flux manufactured by Cookson Electronics that includes b-terpiniol, dimethyl propionic acid, non-ionic surfactant, triethanol amine and diethanol amine) is spread over at least the array region of the device. The stencil is then placed on the array region in or on the flux material. The stencil is relatively easily aligned using an optical microscope since during subsequent heating the holes self-align relatively accurately to the desired underlying ball positions through a mechanism resulting from surface tension effects. Solder balls or balls of another conducting material are then spread over the stencil. If the stencil is maintained at a thickness not substantially exceeding the diameter of the ball then only one ball is positioned in each stencil hole. Thus ball placement is easily accomplished. To complete ball attachment the device with its overlying flux stencil and positioned balls is then heated for typical solder ball compositions to a temperature in the range 220 to 235 degrees Celsius. Because such temperatures tend to scorch paper stencils, such stencils are typically not reusable. However, stencil material and processing costs are extremely low relative to typical techniques and so the fabrication of a new stencil for each procedure is not inconvenient and is extremely cost effective. Additionally, since the stencil is easily produced on site, delays associated with outside vendors are eliminated. Additionally stencil replacements as discussed are not a consideration. Thus the invention results in an efficient, reliable, low volume process for ball array fabrication involving nominal associated costs.

### BRIEF DESCRIPTION OF THE DRAWINGS

FIG. 1 is a plan view of a representative metal fixture;

FIG. 2 is a chart of steps relating to the array fabrication procedure; and

FIG. 3 is a schematic of an illustrative array configuration.

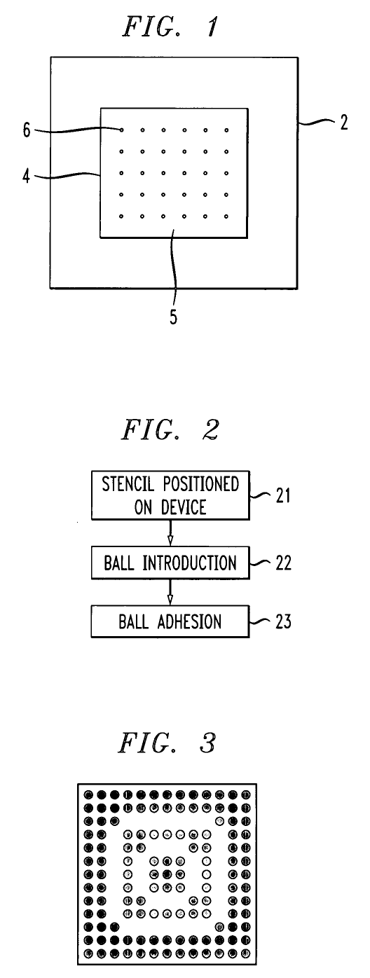

### DETAILED DESCRIPTION

As discussed, the inventive process involves the fabrication of an electronic device such as an integrated circuit by using a stencil produced by laser ablation of a stencil blank. Both flexible and rigid stencils are useful. However, when the device to be processed has a dimension from one point on the device perimeter to another such point of 2.4 mm or greater the surface of the device tends to be non-planar. A flexible stencil better conforms to any non-planarity and thus promotes improved stencil alignment in such devices. In the context of the invention, a flexible stencil is one that undergoes a deflection such that the ratio between 1) displacement from the plane of the major surface of the stencil and 2) the force applied to opposing edges of the stencil without exceeding the yield strength of the stencil, is greater than 0.3 mm per gram. Suitable stencil materials include paper such as card stock denominated cover paper in the trade with a weight density in the range of 100 to 120 pounds and polymeric materials such as polyvinyl materials. Exemplary of suitable paper materials is cover paper with a density of 110 lbs. per 500 sheet ream (300 grams per square meter) with an average thickness of approximately 0.012 inches. Exemplary of suitable polymeric materials are polyvinyl and polyimide materials having a thickness in the range 0.005 to 0.010 inches e.g. a sheet of Kapton™ having a thickness in this range. Although it has been found that polymer and cover paper yield excellent low volume production of devices with ball arrays, the material employed for the stencil is not critical provided it has the necessary flexibility, when desired, and undergoes ablation to form holes of suitable dimensions for a laser beam power density less than 5 watts/sq. mm. Additionally, although less convenient, it is possible to fabricate a flexible stencil by employing a stencil blank that is rigid during hole formation and then made flexible by, for example, thinning.

Since the stencil is subjected to elevated temperatures to induce ball adhesion it is desirable that the stencil does not unacceptably degrade for the processing temperatures employed. Typical ball adhesion temperatures are in the range 220 to 260 degrees Celsius. For polymers generally melting points or softening points above 300 degrees Celsius preferably above 500 degrees Celsius are desirable although lower melting or softening points are acceptable provided the stencil does not unacceptably degrade. Paper stencils typically scorch during the ball adhesion process but generally maintain their dimensional integrity. Nevertheless, paper stencils are typically not reused.

The thickness of the stencil should not be so thick that upon application of a ball mass more than two such balls are constrained in a single hole. Typically, such constraint of two balls is avoided by limiting the stencil thickness to less than 25 percent thicker than the average diameter of the balls being employed. A stencil thickness less than 10% thinner than the ball diameter is generally too thin to adequately constrain a solder ball for subsequent adherence. In an advantageous embodiment the thickness of the stencil is approximately 95 percent of the ball diameter. (Ball diameters are typically not absolutely uniform nor are such balls perfectly spherical. Additionally, the term ball is used generically to include any electrically conducting body, irrespective of shape, to be placed at a connecting point in an array. Therefore, ball diameter is considered the average diameter of the balls employed with the diameter of a ball being the dimension corresponding to a sphere having the same volume as the ball. Similarly, stencil hole diameter is the diameter of a circle having the same area as that of the surface cross sections of the hole.) The stencil is desirably formed of materials that are relatively flat, i.e. its major surfaces have an average excursion from a plane that is a least square fit to such surface that is less than 0.002 inches. Additionally, it is desirable that the stencil be of relatively uniform thickness, i.e. have a thickness measured perpendicular to the major surface with average excursion from the mean thickness of less than 0.001 inches preferably less than 0.0005 inches.

The laser used for ablation should typically have a beam size in the range 0.003 to 0.014 inches preferably 0.003 to 0.005 inches. Generally, the beam shape should be approximately circular but use of other shapes is not precluded. Typical beam spot power densities in the range 1.2 to 5 watts/sq. mm. are adequate to form a well-defined hole as small as 0.014 inches in diameter with typical stencil material. For such power densities the laser beam is typically modulated with on time periods and off time periods in the range from 100 to 190 milliseconds. Control of a laser spot is conventional and is accomplished with commercially available equipment such as a Markem 612 Platemaker that employs a Synrad model 48-1 carbon dioxide laser with a 14 watt average power output at a wavelength in the range 10.57 to 10.63 μm and a command base frequency in the range of 5 to 20 KHz. (Markem Platemakers are manufactured by Markem Corporation of Keene, N.H.)

The procedure employed to position the stencil blank on the sample holder of the laser writing tool is not critical. In one embodiment, two-sided tape with relatively low strength adhesive such as Removable Double Side Tape manufactured by 3M Stationary Products Division is conveniently employed to hold the sample and after stencil formation is also easily removed. To form the stencil hole pattern the beam is directed to a spatial location at which a hole is desired. The beam is then turned on for a time suitable to produce a hole of suitable shape and dimension. Subsequently the beam is extinguished or blanked redirected to another position at which a hole is desired and then this second location is subjected to the beam for a suitable duration. The beam is repetitively repositioned in this manner until the desired hole array pattern is produced. (Although hole arrays are typically formed at the intersections of perpendicular grids, such geometry is not critical. Other geometry involving grids that do not have perpendicular rows and columns or non-grid patterns are producible. Additionally, by suitable control of the beam non-circular holes are producible at desired locations even with circular laser spots.)

The device on which a ball array is to be produced is treated with a flux suitable for the balls to be adhered in a desired pattern. For example, for solder based balls a paste flux having a nominal composition of 25% b-terpiniol, 15% dimethyl propionic acid, 20% non-ionic surfactant, 3% triethanol amine and 3% diethanol amine is acceptable. A typical suitable paste for solder balls is Alpha WS 600 manufactured by Cookson Electronics located at Jersey City, N.J. Although a paste flux is desirable, other fluxes are also useful. Conventional techniques for applying the flux are employed. For example, paste fluxes are advantageously applied using a flexible roller such as a rubber roller. Sufficient roller pressure is employed so that generally the average flux thickness is less than 0.001 inches. Typical fluxes are corrosive. Therefore, the composition of the mask material should be chosen so that the diameter of the holes of the resulting stencil does not change more than 10 percent in diameter due to chemical interactions with the flux. Additionally, it is undesirable for the ablation process to produce debris that remains affixed to the device being processed. Therefore, it is useful to choose a stencil material together with a laser power such that the ablated material is vaporized.

In one step, 21 in FIG. 2, of the inventive process a stencil having a suitable hole pattern is positioned on the device to be treated so that the holes of the pattern align with the desired positions for the conducting balls. Typically the stencil has a perimeter that is coextensive with the underlying device. The stencil perimeter advantageously does not have excursions greater than 0.005 inches beyond the device periphery. Alignment is relatively easily accomplished using a conventional optical microscope. Microscope magnification in the range 5× to 50× is generally adequate. Microscope alignment is used to position the holes in the stencil so that at least 75 percent of the corresponding area in the underlying device to be occupied by a ball is within the hole perimeter. Generally the hole when in this position advantageously should not extend more than 0.005 inches beyond the periphery that will be subsumed by the ball upon adherence. Misalignment within these parameters typically does not induce difficulties since the surface tension between the ball and the underlying metal pad of the device during the adhesion process self-aligns the mask to the desired position.

In another step, 22 in FIG. 2, balls are introduced into the holes of the stencil. As previously discussed, it is desirable that the thickness of the stencil is chosen so that not more one ball is present in each hole that corresponds to a desired position for ball placement. The balls are introduced by placing a substantial surplus of balls on the exposed stencil surface and providing some stimulus for movement of the balls to ensure placement of a ball in each such stencil hole. Excess balls—those that do not occupy hole locations—are removed by sweeping away with a soft-bristled brush.

In another step, 23 in FIG. 2, adherence of the balls to the underlying pad of the device, is induced by bringing the ball temperature to a level adequate to produce adhesion between the ball and the underlying pad. For typical solder ball compositions such as tin based alloys, temperatures in the range 220 to 250 degrees C are employed for time periods in the range 45 seconds to 1.5 minutes. The exact temperature employed depends on the device size and other parameters such as substrate thickness as well as quantity and composition of the balls. A control sample is employed to determine a suitable temperature for a particular device, and parameter domain. The source of heat to produce suitable processing temperatures is not critical. Conventional heat sources such as a hot plate or belt oven are useful. Generally, after adhesion the device is cooled by termination of heat introduction and positioning on a heat sink for 1 to 3 minutes or longer before stencil removal. The stencil is mechanically removed and excess flux eliminated such as by treatment with deionized water. It is possible to augment flux removal by mechanical agitation such as with a brush. Typically excess flux material is adequately removed by treatments with deionized water exceeding about 15 seconds.

### EXAMPLE

An AutoCAD 2000 drawing program was employed to produce a representation of the desired array (shown in FIG. 3) for an Agere Systems 225 VTFSBGAB package type with darkened circles representing corresponding stencil holes and lines corresponding to the stencil boundaries. The holes had a diameter of 0.016 inches and the center to center spacing between adjacent holes as shown in FIG. 3 was 0.65 mm. The resulting computer file was loaded onto a floppy disk and then transferred to the host computer (Apple Power Macintosh 8500 computer) for a Markem 612 Platemaker. Using the Adobe Photoshop 3.0 program, the stencil file was loaded into the Photoshop program and subsequently a graphic picture of the stencil loaded in the computer's clipboard. The operating software for the Markem Platemaker was opened and a sample plate file was loaded and then cleared to create a blank image. The stored image of the array pattern on the clipboard was loaded on the plate file using a command denominated Edit, Paste. A standard paper business card was attached to a 3 inch by 5 inch steel metal plate using ¾ inch wide double-sided removable Scotch® tape. The plate with its attached business card was inserted into the Platemaker sample holder with the card facing the laser light source of the Platemaker. A command denominated Make Plate was executed to induce stencil formation in the business card. After several minutes the burn process was completed, the plate removed and the resulting stencil lifted from the plate using a blunt tipped tweezer.

A 225 VTFSBGAB package was subjected to a small amount of flux (approximately 3 grams) applied to the ball-side surface using a soft bristled brush. The side of the device opposite that carrying the stencil was placed directly on the ceramic top of a hot plate that was set to 230 degrees C. A wooden shaft with a cotton tip was employed to remove any residual solder from the array surface. After two minutes, the device was removed from the hot plate and cooled for 30 seconds on an aluminum heat sink. The array was then inserted under a stream of deionized water and brushed with a conventional toothbrush to remove flux and other debris. The device was then mechanically dried using an ionized air gun.

A small amount of flux (approximately 3 grams of Alpha WS 600) was applied to the device pad surface and a rubber roller approximately 2 inch length and 1 inch diameter was manually rolled across the device to produce a thin, relatively uniform flux coating. The device was placed under a 5× optical microscope and the stencil was placed on top of the package with the edges of the stencil flush to the corresponding edges of the package body. Observation through the microscope confirms that the stencil holes were aligned with the pads on the package body. Using a small spoon, a small quantity of solder spheres, approximately 0.2 grams, were poured on the stencil. The solder spheres were 0.012 inches in diameter and had a composition of 96.5 weight percent tin, 3 weight percent silver, and 0.5 weight percent copper as an alloy. (The solder sphere was a standard product of Cookson Electronics.) Using a plastic shaft having a foam tip, the solder spheres were mechanically pushed across the stencil inducing spheres to fall into the stencil holes. The tackiness of the paste flux prevented the stencil from moving and causing a misalignment. After all the stencil holes were filled with a solder sphere, the excess spheres were pushed off the stencil and collected for subsequent reuse.

The device was placed on the ceramic surface of a hot plate with the stencil remote from the hot plate surface. The hot plate was set for a temperature of 230 degrees Celsius and the device was subjected to the corresponding heat for approximately one minute. During the heating process, the stencil was observed to shift slightly as part of a self-alignment of the stencil to the exact position of the package pads. After the one-minute heat treatment, the part was removed from the hot plate and cooled for 30 seconds on an aluminum heat sink. The stencil was then removed with a tweezer. The package was inserted under a stream of deionized water and brushed with a conventional toothbrush to remove any residual flux. The package was mechanically dried using an ionized air gun. Visual observation under an optical microscope verified that all the solder balls were attached to corresponding pads with no bridges between the balls and with all the balls free from deformities or other surface irregularities.

1. A method of fabricating an electronic device including a plurality of balls that contact said electronic device at electrically conducting device pads arranged in a first pattern, said method comprising obtaining a stencil having holes formed by laser ablation in a stencil blank such that said holes geometrically correspond to said device pads, aligning said holes with said device pads that geometrically correspond, introducing said balls to said pads so that said balls are positioned by said holes and inducing said balls to adhere to said device pads.

2. The method of claim 1 wherein said pattern comprises a grid.

3. The method of claim 1 wherein said balls comprise solder.

4. The method of claim 1 wherein said stencil is rigid.

5. The method of claim 1 wherein said stencil is flexible.

6. The method of claim 5 wherein said stencil comprises paper.

7. The method of claim 5 wherein said stencil comprises a polymer.

8. The method of claim 7 wherein said polymer comprises a polyvinyl polymer.

9. The method of claim 1 wherein said stencil comprises paper.

10. The method of claim 1 wherein said stencil comprises a polymer.

11. The method of claim 10 wherein said polymer comprises a polyvinyl polymer.

12. The method of claim 1 wherein said electronic device comprises an integrated circuit.

13. The method of claim 1 wherein said electronic device comprises a passive electronic device.

14. The method of claim 1 wherein said balls are induced to adhere by subjecting said balls to a temperature in the range of 220 to 260 degrees Celsius.

15. The method of claim 1 wherein said laser ablation is induced with a laser having a beam spot power density in the range 1.2 to 5 watts/sq. mm.

16. The method of claim 1 wherein said laser ablation is induced using a carbon dioxide laser.

17. The method of claim 1 wherein the thickness of said stencil is less than 25% thicker than the average diameter of said balls.

18. The method of claim 1 wherein flux is introduced to said device pads before said stencil is aligned.

19. The method of claim 18 wherein said flux comprises a solder flux.
